(19) United States
(12) Patent Application Publication
(10) Pub. No.: US 2023/0103134 A1
(43) Pub. Date: Mar. 30, 2023

(54) TEMPERATURE STIMULATION UNIT AND AMUSEMENT MACHINE

(71) Applicant: OMRON Corporation, Kyoto-shi (JP)

(72) Inventors: Hiroaki SUGIYAMA, Kyoto-shi (JP); Hiroyuki ONITSUKA, Kyoto-shi (JP); Hitoshi SAKAMOTO, Kyoto-shi (JP); Eiji YASUDA, Ichinomiya-shi (JP)

(73) Assignee: OMRON Corporation, Kyoto-shi (JP)

(21) Appl. No.: 17/892,185

(22) Filed: Aug. 22, 2022

(30) Foreign Application Priority Data
Sep. 29, 2021 (JP) 2021-159594

(51) Int. Cl. A63F 7/36; F25B 21/04; H05K 5/00

(52) U.S. Cl. CPC A63F 7/36; F25B 21/04; H05K 5/0017; A63F 7/022

(57) ABSTRACT

A temperature stimulation unit according to one or more embodiments may include a cover, a case including a top portion with an opening, and a control board. The case may include a bottom portion and a side portion having a through-hole. The bottom portion and the side portion may define a clearance at least with the control board.

### CROSS-REFERENCE TO RELATED APPLICATION

This application claims priority to Japanese Patent Application No. 2021-159594 filed on Sep. 29, 2021, the contents of which are incorporated herein by reference.

### FIELD

The present disclosure relates to a temperature stimulation unit and an amusement machine including the temperature stimulation unit.

### BACKGROUND

A known temperature stimulation unit includes a temperature changer including a thermoelectric element (e.g., a Peltier element) that can change the temperature of a touch portion touchable by a player to a temperature different from ordinary temperature to stimulate the player. For example, Patent Literature 1 describes a temperature changer that can change the temperature of a touch portion touchable by a player.

### CITATION LIST

### Patent Literature

Patent Literature 1: Japanese Patent No. 6368182

### SUMMARY

The temperature stimulation unit includes a case having through-holes (vents) to dissipate heat from the temperature changer. A drink spilled on the amusement machine by a player may, for example, enter the housing of the amusement machine and then enter the temperature stimulation unit through the through-holes. The liquid may reach a control board in the temperature stimulation unit, causing failure of the control board.

In response to the above issue, one or more embodiments may be directed to a technique for preventing failure of a control board caused by a liquid entering a temperature stimulation unit.

A temperature stimulation unit according to one or more embodiments is installable on a back of a touch portion touchable by a player to provide a sense of a temperature different from an ordinary temperature to the player. The temperature stimulation unit includes a cover that comes in contact with the back of the touch portion, a case including a top portion with an opening through which the cover is exposed, and components accommodated in the case. The components include a temperature changer located on a back surface of the cover to change a temperature of the cover, a heat sink located opposite to the cover across the temperature changer, and a control board that controls an operation of the temperature changer. The case includes a bottom portion opposite to the top portion across the components and includes a side portion connecting the top portion and the bottom portion. The bottom portion and the side portion have a through-hole. The bottom portion and the side portion define a clearance at least with the control board.

In the above structure, the case has the through-hole in the side portion and also in the bottom portion. A liquid entering the temperature stimulation unit (the case) through the through-hole in the side portion may thus be discharged from the temperature stimulation unit (the case) through the through-hole in the bottom portion. In other words, a liquid entering the temperature stimulation unit may be discharged from the temperature stimulation unit without reaching the control board. The above-described structure prevents failure of the temperature changer caused by a liquid entering through the through-hole in the side portion. The through-hole located both in the bottom portion and in the side portion also may allow efficient heat dissipation from the temperature changer.

The bottom portion and the side portion may define a clearance with the components. The above structure may prevent a liquid entering the temperature stimulation unit from flowing along the heat sink accommodated in the case and reaching the control board.

The control board may be between the heat sink and the bottom portion. The case may include a support on an inner surface of the bottom portion. The support may support the control board with a clearance left between the control board and the bottom portion.

When the support is located on the side portion to support the control board with a clearance left between the control board and the bottom portion, a liquid may flow along the inner surface of the side portion and along the support on the side portion and reach the control board. In the above structure, the support is located on the bottom portion and thus may prevent a liquid from flowing along the support and reaching the control board.

The through-hole may include a through-hole extending from the bottom portion to the side portion at a corner connecting the bottom portion and the side portion. The above structure may allow a liquid entering the temperature stimulation unit to be discharged more efficiently. The structure also may allow more efficient heat dissipation from the temperature changer.

The temperature changer may include a Peltier element. The temperature changer may include the Peltier element to achieve the above structure easily.

One or more embodiments is directed to an amusement machine including a touch portion touchable by a player to provide a sense of a temperature different from an ordinary temperature to the player, and the temperature stimulation unit on a back of the touch portion.

The technique according to one or more embodiments may prevent failure of the control board caused by a liquid entering the temperature stimulation unit.

### BRIEF DESCRIPTION OF THE DRAWINGS

FIG. 1 is a schematic diagram illustrating a perspective view of an amusement machine according to one or more embodiments.

FIG. 2 is a diagram illustrating a perspective view of a touch portion on an upper wall of an amusement machine and a temperature stimulation unit on a back of a touch portion.

FIG. 3 is a diagram illustrating a perspective view of a temperature stimulation unit with an upper wall and a touch portion cut along line A and viewed in a direction indicated by arrows in FIG. 2.

FIG. 4 is a diagram illustrating an enlarged front view of an upper wall and a touch portion in a state, such as is shown in FIG. 3.

FIG. 5 is a diagram illustrating a perspective view of a temperature stimulation unit.

FIG. 6 is a diagram illustrating a perspective view of a temperature stimulation unit as viewed from an angle different from an angle, such as is shown in FIG. 5.

FIG. 7 is a diagram illustrating an exploded view of a temperature stimulation unit.

FIG. 8 is a diagram illustrating a perspective view of a lower case portion of a temperature stimulation unit.

FIG. 9 is a diagram illustrating a perspective view of a temperature stimulation unit cut along line B and viewed in a direction indicated by arrows in FIG. 5.

FIG. 10 is a diagram illustrating a perspective view of a temperature stimulation unit cut along a line and viewed from an angle different from an angle as shown in FIG. 9.

### DETAILED DESCRIPTION

One or more embodiments will be described below with reference to the drawings. The embodiments described below are a merely exemplary in all aspects. The embodiments may be variously modified or altered without departing from the intended scope of the invention. More specifically, one or more embodiments may be implemented as appropriate using a configuration specific to each embodiment or may use a combination or combinations of aspects from different embodiments.

### First Embodiment

### 1. Example Use

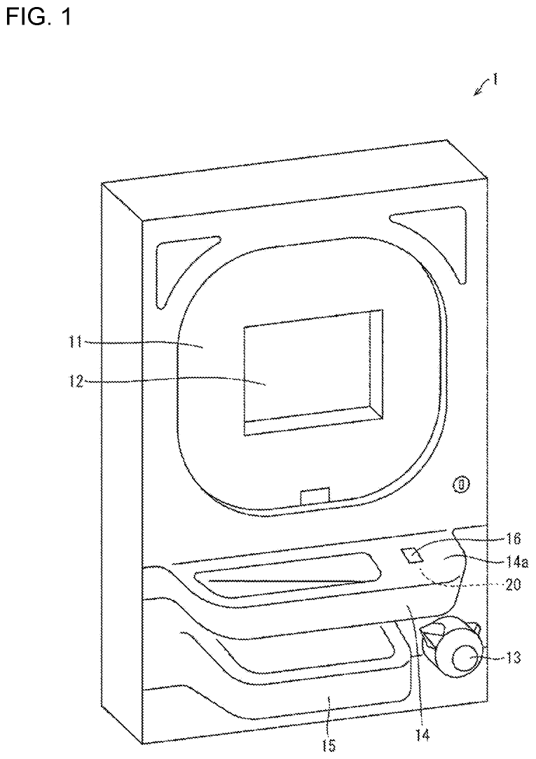

An example use of a temperature stimulation unit 20 will now be described with reference to FIGS. 1 to 4, 9, and 10. As shown in FIGS. 1 to 4, the temperature stimulation unit 20 is located on the back of a touch portion 16 on an upper wall 14a forming the upper surface of an upper tray 14 on an amusement machine 1. The temperature stimulation unit 20 can change the temperature of the touch portion 16 touchable by a player to a temperature different from ordinary temperature to stimulate the player.

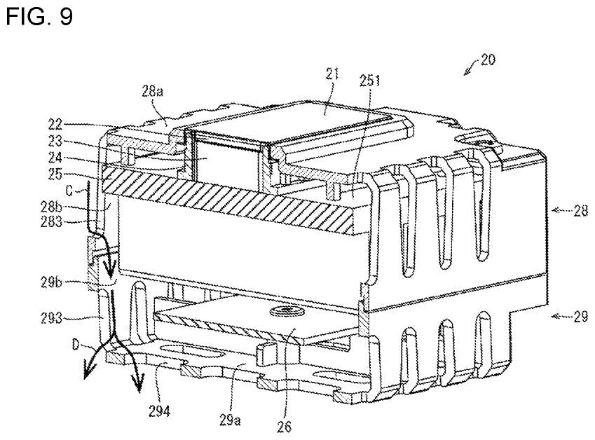

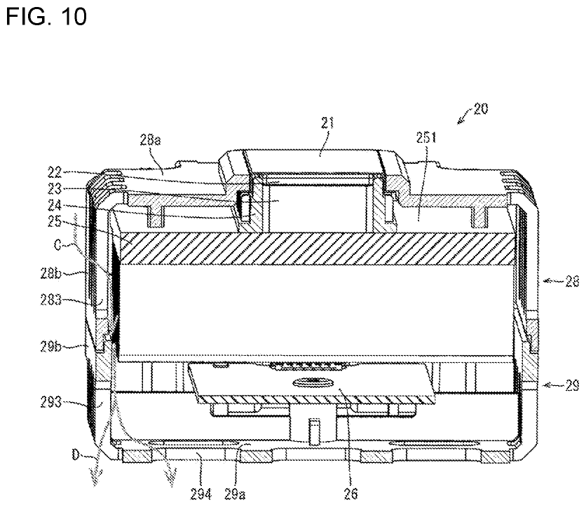

As shown in FIGS. 9 and 10, the temperature stimulation unit 20 includes a cover 21 provided to come in contact with the touch portion 16, a temperature changer 22 for changing the temperature of the cover 21, and a control board 26 for controlling the operation of the temperature changer 22. The temperature stimulation unit 20 includes a case 27 including side portions 28b and 29b with first through-holes 283 as vents and including a bottom portion 29a with second through-holes 294. The bottom portion 29a and the side portions 28b and 29b define a clearance with at least the control board 26.

When a liquid is spilled on the upper wall 14a by the player and enters the temperature stimulation unit 20 through the first through-holes 283, the liquid flows through the clearance and is discharged from temperature stimulation unit 20 through the second through-holes 294. Such action prevents failure of the control board 26 caused by a liquid entering the temperature stimulation unit 20.

### 2. Example Structure

### 1. Overview of Amusement Machine 1

FIG. 1 is a schematic perspective view of the amusement machine 1 according to one or more embodiments. The temperature stimulation unit 20 according to one or more embodiments is used for a pachinko machine as an example amusement machine. However, the temperature stimulation unit 20 may be used for any other machine or apparatus. The temperature stimulation unit 20 may be used for, for example, a slot machine, any of various gaming machines, or any of various exhibition apparatuses.

As shown in FIG. 1, the amusement machine 1 includes a gaming section 11, a display 12, a handle 13, the upper tray 14, and a lower tray 15. The gaming section 11 is a section in which a gaming ball (gaming medium) moves after being shot with the handle 13. The display 12 displays various presentation images in accordance with the status of a game or various images indicating operational guide information for a user. The upper tray 14 holds gaming balls obtained by the player. The lower tray 15 holds gaming balls overflowing from the upper tray 14.

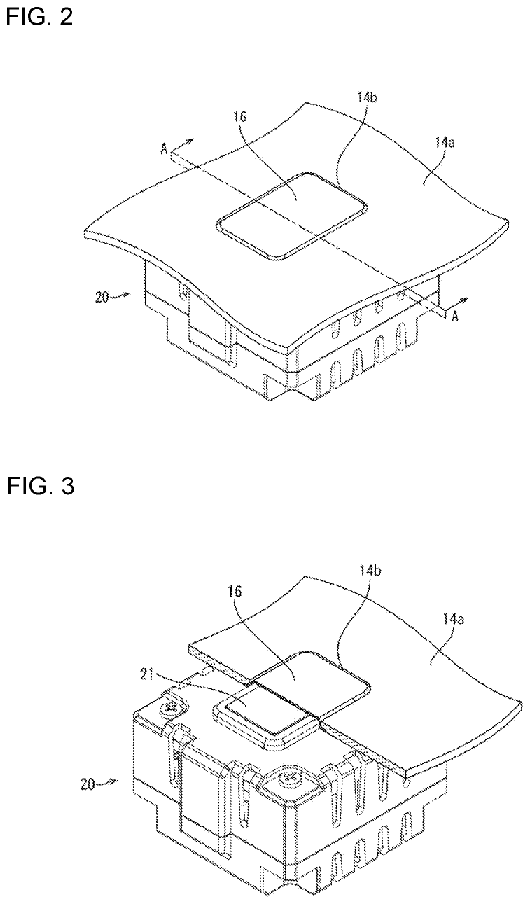

The upper wall 14a (a portion of the housing of the amusement machine 1) forming the upper surface of the upper tray 14 includes the touch portion 16 touchable by the player to provide a sense of a temperature different from ordinary temperature to the player. The temperature stimulation unit 20 is located on the back of the touch portion 16 to change the temperature of the touch portion 16. The touch portion 16 and the temperature stimulation unit 20 will be described later with reference to FIGS. 2 to 4. The upper wall 14a may include an operable portion such as a switch (not shown).

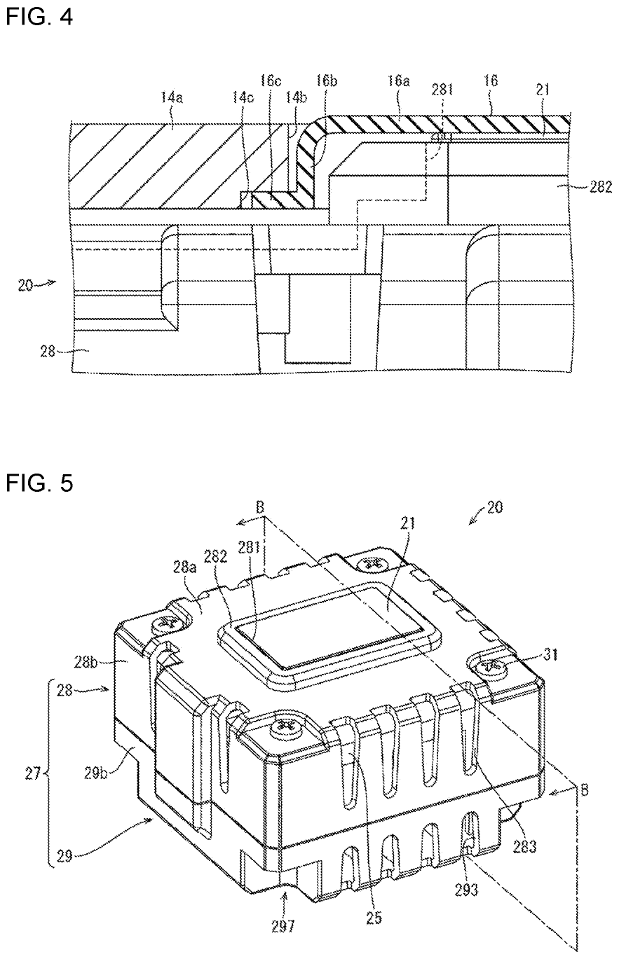

FIG. 2 is a perspective view of the touch portion 16 on the upper wall 14a and the temperature stimulation unit 20 on the back of the touch portion 16 (on the back of the upper wall 14a). FIG. 3 is a perspective view of the temperature stimulation unit 20 with the upper wall 14a and the touch portion 16 cut along line A and viewed in the direction indicated by arrows in FIG. 2. FIG. 4 is an enlarged front view of the upper wall 14a and the touch portion 16 in the state shown in FIG. 3.

As shown in FIGS. 2 to 4, the upper wall 14a has a substantially rectangular upper wall opening 14b receiving the touch portion 16. More specifically, the upper wall 14a has upper wall cutouts 14c receiving second extending portions 16c (described later) at the bottom of the upper wall opening 14b on its side surface. The touch portion 16 includes a main surface 16a, first extending portions 16b, and the second extending portions 16c. The main surface 16a has a shape corresponding to the upper wall opening 14b and is received in and defines the front surface of the upper wall opening 14b. The first extending portions 16b extend downward from the longer sides of the main surface 16a along the side portion of the upper wall opening 14b. Each second extending portion 16c extends substantially parallel to the main surface 16a from an end of the corresponding first extending portion 16b (refer to FIG. 4). The second extending portions 16c are received in the upper wall cutouts 14c. The touch portion 16 is fixed to the upper wall 14a with, for example, adhesion.

As shown in FIGS. 3 and 4, the temperature stimulation unit 20 is located on the back of the touch portion 16. More specifically, the temperature stimulation unit 20 includes the case 27 including a top portion 28a in contact with the back of the upper wall 14a. The cover 21 in the temperature stimulation unit 20 is in contact with the back of the touch portion 16. More specifically, the case 27 includes a protrusion 282 on the top portion 28a. The protrusion 282 has an opening 281 inside the protrusion 282 and protrudes outside the case 27. The protrusion 282 is received in the upper wall opening 14b and faces the main surface 16a located above the upper wall opening 14b. The cover 21 is exposed through the opening 281. More specifically, the cover 21 partly protrudes outside the protrusion 282 in a front view and can be in contact with the back of the upper wall 14a.

The temperature stimulation unit 20 with the above-described structure is located on the back of the touch portion 16. The temperature stimulation unit 20 may be at another position. For example, the temperature stimulation unit 20 may be located on the back of a sidewall that is another portion of the housing of the amusement machine.

### 2. Structure of Temperature Stimulation Unit 20

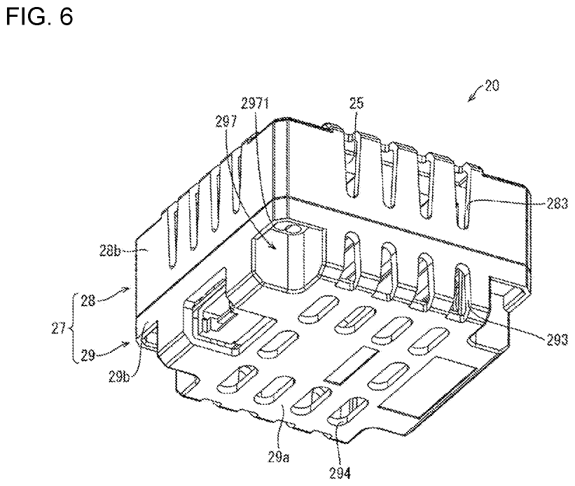

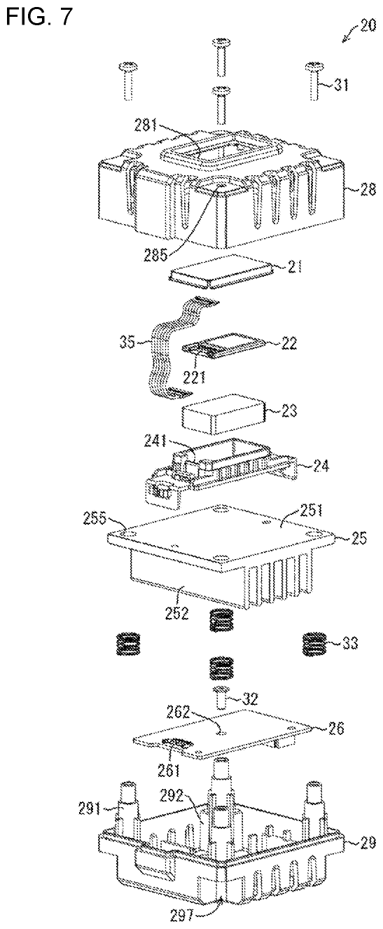

FIG. 5 is a perspective view of the temperature stimulation unit 20. FIG. 6 is a perspective view of the temperature stimulation unit 20 as viewed from an angle different from the angle for FIG. 5. FIG. 7 is an exploded view of the temperature stimulation unit 20. The temperature stimulation unit 20 according to one or more embodiments will now be described with reference to FIGS. 5 to 7.

As shown in FIGS. 5 to 7, the temperature stimulation unit 20 includes the case 27, the cover 21, and components accommodated in the case 27 including the temperature changer 22, a spacer 23, a fastener 24, a heat sink 25, a control board 26, and the coil springs 33 (refer to FIG. 7). The temperature stimulation unit 20 is located on the back of the touch portion 16 (refer to FIGS. 1 to 4) touchable by the player to provide a sense of a temperature different from ordinary temperature to the player.

The case 27 is substantially rectangular and includes the top portion 28a in contact with the upper wall 14a (refer to FIGS. 2 to 4), a bottom portion 29a opposite to the top portion 28a across the components accommodated in the case 27, and side portions 28b and 29b connecting the top portion 28a and the bottom portion 29a. In the case 27, a position adjacent to the top portion 28a is referred to as an upper position, and a position adjacent to the bottom portion 29a is referred to as a lower position.

The case 27 includes an upper case portion 28 including the top portion 28a and a lower case portion 29 including the bottom portion 29a. Of the side portions 28b and 29b, a side portion included in the upper case portion 28 is an upper side portion 28b, and a side portion included in the lower case portion 29 is a lower side portion 29b.

The upper case portion 28 includes the protrusion 282 at the center of the top portion 28a and protruding outside (above) the upper case portion 28. The protrusion 282 has the opening 281 inside the protrusion 282. The upper case portion 28 has upper case holes 285 (refer to FIG. 7) for receiving screws 31 at the four corners of the top portion 28a.

The lower case portion 29 includes lower case protrusions 292 protruding upward at the four corners of the bottom portion 29a. Each lower case protrusion 292 includes a shaft 291 on the upper surface (refer to FIG. 7). The shafts 291 protrude toward the top portion 28a through the heat sink 25 (described later). Each shaft 291 has a shaft threaded hole 2915 extending axially from the end of the corresponding protrusion. The upper case portion 28 is fastened to the lower case portion 29 with the screws 31 being screwed in the shaft threaded holes 2915 through the upper case holes 285.

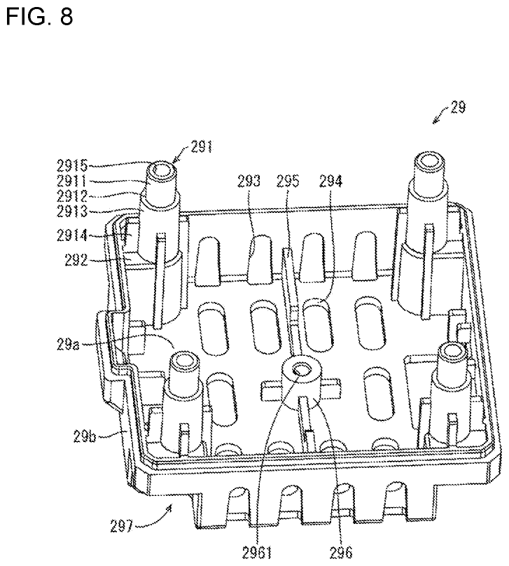

The lower case portion 29 has lower case cutouts 297 outside the lower case protrusions 292. Each lower case cutout 297 includes a support-receiving portion 2971 on the upper surface. The support-receiving portions 2971 are, for example, supported on support members (not shown) located on a lower wall forming the lower surface of the upper tray 14 (refer to FIG. 1). The structure of the lower case portion 29 will be described in detail later with reference to FIG. 8.

The case 27 has through-holes in the bottom portion 29a and the side portions 28b and 29b. More specifically, the upper case portion 28 has the first through-holes 283 (through-hole) extending from the top portion 28a to the upper side portion 28b at the upper corners (the upper edges of the upper side portion 28b) connecting the top portion 28a and the upper side portion 28b (refer to FIGS. 5 and 6). In the example of FIGS. 5 to 7, three upper corners each have four first through-holes 283, and one upper corner has two first through-holes 283. The lower case portion 29 has the second through-holes 294 (through-hole) in an edge portion of the bottom portion 29a (refer to FIG. 6). In the example of FIG. 6, the bottom portion 29a has ten second through-holes 294.

The temperature stimulation unit 20 thus has the through-holes serving as vents both in the bottom portion 29a and the side portions 28b and 29b of the case 27. Such venting allows efficient heat dissipation from the temperature changer 22 (described later).

The lower case portion 29 may have third through-holes 293 (through-hole) extending from the bottom portion 29a to the lower side portion 29b at the lower corners (the lower edges of the lower side portion 29b) connecting the bottom portion 29a and the lower side portion 29b (refer to FIGS. 5 and 6).

The cover 21 is received in the opening 281 inside the protrusion 282. The cover 21 has a profile corresponding to the opening 281 and covers the opening 281. The cover 21 thus protects the components accommodated in the temperature stimulation unit 20. The cover 21 is exposed through the opening 281 to come in contact with the back of the touch portion 16 (refer to FIGS. 1 to 4). The cover is formed from, for example, a thermally conductive metal. The cover 21 can thus transfer heat from the temperature changer 22 (described later) to the touch portion 16.

The temperature changer 22 is a module in contact with the back surface of the cover 21 to change the temperature of the cover 21 upon being energized. The temperature changer 22 may include a Peltier element that is a thermoelectric element. When direct current flows through the Peltier element, one of its front and back surfaces dissipates heat and the other surface absorbs heat based on the direction of the direct current. The degree of heating and cooling varies in accordance with the value (amplitude) of the direct current.

The temperature changer 22 including the Peltier element has the front surface that faces the cover 21 dissipating or absorbing heat. To heat the cover 21, the temperature changer 22 has the front surface dissipating heat and has the back surface that faces the heat sink 25 (described later) absorbing heat. To cool the cover 21, the temperature changer 22 has the front surface absorbing heat and the back surface dissipating heat. The temperature changer 22 is connected to the control board 26 with a harness 35. More specifically, the harness 35 connects a temperature changer connector 221 in the temperature changer 22 and a control board connector 261 in the control board 26.

The spacer 23 is a heat transferrer in contact with the back surface of the temperature changer 22 and holding the temperature changer 22 to allow the temperature changer 22 to protrude outside (above) the upper case portion 28. The spacer 23 is sized to be fit in the opening 281. The fastener 24 is looped and has a fastener opening 241 inside the fastener 24 to receive the temperature changer 22 and the spacer 23. The fastener 24 fastens the temperature changer 22 and the spacer 23 in the front-back and left-right directions.

The heat sink 25 is a heat dissipator located opposite to the cover 21 across the temperature changer 22 (facing the back surface of the temperature changer 22) and formed from, for example, a thermally conductive metal. The heat sink 25 includes a heat sink base 251 and multiple fins 252.

The heat sink base 251 is in contact with the spacer 23. The spacer 23 as a heat transferrer can thus transfer heat between the heat sink 25 and the temperature changer 22. The spacer 23 and the heat sink 25 may be integral with each other. The fins 252 extend downward from the heat sink base 251. The heat sink 25 can thus efficiently dissipate heat from the temperature changer 22 to the outside through the fins 252. The heat sink base 251 has heat sink holes 255 at the four corners of its front surface. The heat sink holes 255 receive distal end portions 2911 of the shafts 291 (refer to FIG. 8, described later).

The control board 26 is between the heat sink 25 and the bottom portion 29a (below the heat sink 25) and controls the operation of the temperature changer 22. The control board 26 controls the direction of a current flowing through the Peltier element in the temperature changer 22 in response to a signal from a control unit (not shown) in the amusement machine 1. The control board 26 can thus cause the temperature changer 22 to have its front surface dissipating heat or absorbing heat (to heat or cool the cover 21).

The control board 26 has a control board hole 262 at the center of its main substrate. The control board 26 is fastened to the lower case portion 29 below the heat sink 25 with a screw 32 being screwed in a fastener threaded hole 2961 (refer to FIG. 8, described later) through the control board hole 262. The control board 26 may be at any other position. For example, the control board 26 may be on a side portion in the case 27 and may have the main surface facing the side portions 28b and 29b.

The coil springs 33 urge the cover 21 and the temperature changer 22 in a direction to cause the cover 21 and the temperature changer 22 to protrude outside the case 27 through the opening 281. More specifically, each coil spring 33 is located on the axis of the corresponding shaft 291 below the heat sink base 251. The coil springs 33 are in contact with the back surface of the heat sink base 251 and urge the cover 21, the temperature changer 22, the spacer 23, and the heat sink 25 upward.

Although the temperature stimulation unit 20 according to one or more embodiments includes the coil springs 33, the coil springs 33 may be eliminated.

FIG. 8 is a perspective view of the lower case portion 29. As shown in FIG. 8, the lower case portion 29 includes the shafts 291, a control board support 295 (support), and a control board fastener 296 (support).

The shafts 291 protrude from the bottom portion 29a toward the top portion 28a through the heat sink 25. The lower case portion 29 is fastened to the upper case portion 28 with the shafts 291. In the example of FIG. 8, the shafts 291 are located on the upper surfaces of the lower case protrusions 292 at the four corners of the bottom portion 29a. In other words, the lower case portion 29 includes four shafts 291.

Each shaft 291 includes a substantially cylindrical base 2913, a substantially cylindrical distal end portion 2911 having a smaller outer diameter than the base 2913, and a mount 2914. Each mount 2914 protrudes radially from the side surface of the corresponding base 2913 on a portion of the corresponding shaft 291 adjacent to the bottom portion 29a (on a lower portion of the corresponding shaft 291). Each shaft 291 has the shaft threaded hole 2915 extending axially from the end of the corresponding protrusion. Each distal end portion 2911 has the outer diameter smaller than the inner diameter of each heat sink hole 255. The distal end portions 2911 are received in the heat sink holes 255 and protrude above the heat sink 25. Each base 2913 has the outer diameter larger than the inner diameter of each heat sink hole 255. At least the bases 2913 are not received in the heat sink holes 255. Each heat sink hole 255 is movable on the axis of the corresponding distal end portion 2911 and immovable below a step 2912 defined by the corresponding distal end portion 2911 and the corresponding base 2913.

Each of the four shafts 291 includes the coil spring 33 on its axis. Each coil spring 33 is located on the corresponding shaft 291 between the heat sink 25 and the corresponding mount 2914. More specifically, each coil spring 33 is located on the axis of the corresponding shaft 291 between the back surface of the heat sink base 251 and the upper surface of the corresponding mount 2914. The coil springs 33 thus urge the heat sink 25 upward at the four corners of the bottom portion 29a.

The control board support 295 protrudes upward from the bottom portion 29a at the center of the control board 26 (refer to FIG. 7) in the longitudinal direction and at both ends of the control board 26 in the transverse direction. The control board support 295 has an upper surface to receive the control board 26 and supports the control board 26.

The control board fastener 296 is a shaft protruding upward at the center of the bottom portion 29a. The control board fastener 296 has the fastener threaded hole 2961 extending axially from the end of a protrusion. The control board 26 is supported from below on the control board support 295 and the control board fastener 296 with the screw 32 being screwed in the fastener threaded hole 2961 through the control board hole 262 (refer to FIG. 7).

### 3. Effects of Temperature Stimulation Unit 20

FIG. 9 is a perspective view of the temperature stimulation unit 20 cut along line B and viewed in the direction indicated by arrows in FIG. 5. FIG. 10 is a perspective view of the temperature stimulation unit cut along the line as in FIG. 9 and viewed from an angle different from the angle for FIG. 9.

As shown in FIGS. 9 and 10, the temperature changer 22 has the front surface in contact with the back surface of the cover 21, and has the back surface in contact with the spacer 23. When a current is applied to the temperature changer 22 in a predetermined direction, the temperature changer 22 has the front surface dissipating heat to heat the cover 21. Heat is transferred from the cover 21 to the touch portion 16 (refer to FIGS. 1 to 4) in contact with the cover 21, thus heating the touch portion 16. The temperature changer 22 has the back surface absorbing heat to draw heat with the heat sink 25.

When a current is applied to the temperature changer 22 in the direction opposite to the direction for heating, the temperature changer 22 has the front surface absorbing heat to cool the cover 21. Heat is drawn from the touch portion 16 in contact with the cover 21, thus cooling the touch portion 16. The temperature changer 22 has the back surface generating heat that is then dissipated by the heat sink 25.

In other words, the operation of the temperature changer 22 is controlled to change the temperature of the touch portion 16 in the amusement machine 1 to a temperature different from ordinary temperature. The temperature stimulation unit 20 can thus provide a sense of a temperature different from ordinary temperature to the player through the touch portion 16. The heat sink 25 reduces a temperature change of the temperature changer 22 caused by heat transfer from the temperature changer 22 to the touch portion 16. Such heat transfer prevents thermal damage or other failure of the temperature changer 22.

As shown in FIGS. 9 and 10, the first through-holes 283 extend from the top portion 28a to the upper side portion 28b to dissipate heat from the temperature changer 22. A drink spilled on the amusement machine 1 by the player may, for example, enter the upper wall 14a of the amusement machine 1, flow along the path indicated by an arrow C in FIGS. 9 and 10, and enter the temperature stimulation unit 20 through the first through-holes 283.

The temperature stimulation unit 20 according to one or more embodiments also has the second through-holes 294 in an edge portion of the bottom portion 29a of the lower case portion 29. The bottom portion 29a and the side portions 28b and 29b define a clearance with at least the control board 26. A liquid entering the temperature stimulation unit 20 (the case 27) through the first through-holes 283 can thus be discharged from the temperature stimulation unit 20 (the case 27) through the second through-holes 294. More specifically, a liquid entering the temperature stimulation unit 20 flows along the side portions 28b and 29b and the bottom portion 29a (along the path indicated by an arrow D in FIGS. 9 and 10) and is discharged from the temperature stimulation unit 20 without reaching the control board 26. The above-described structure prevents failure of the temperature changer 22 caused by a liquid entering through the first through-holes 283. The case 27 has the through-holes both in the bottom portion 29a and in the side portions 28b and 29b, thus allowing efficient heat dissipation from the temperature changer 22.

The bottom portion 29a and the side portions 28b and 29b define a clearance also with the heat sink 25 accommodated in the case (refer to FIG. 10). The above-described structure prevents a liquid entering the temperature stimulation unit 20 through the first through-holes 283 from flowing along the heat sink 25 and reaching the control board 26 (located below the heat sink 25).

As shown in FIG. 8, the lower case portion 29 includes the support (the control board support 295 and the control board fastener 296) on the inner surface of the bottom portion 29a. The support supports the control board 26 with a clearance left between the control board 26 and the bottom portion 29a. When the support is located on the side portions 28b and 29b to support the control board 26 with a clearance left between the control board 26 and the bottom portion 29a, a liquid may flow along the inner surfaces of the side portions 28b and 29b and along the support on the side portions 28b and 29b and reach the control board 26. In the above structure, the support is located on the bottom portion 29a and thus prevents a liquid from flowing along the support and reaching the control board 26.

As shown in FIGS. 9 and 10, the structure may include the third through-holes 293 extending from the bottom portion 29a to the lower side portion 29b. The structure allows a liquid entering the temperature stimulation unit 20 to be discharged from the temperature stimulation unit 20 more efficiently through both the second through-holes 294 and the third through-holes 293. The structure also allows more efficient heat dissipation from the temperature changer 22 through the first through-holes 283, the second through-holes 294, and the third through-holes 293.

### APPENDIXES

The embodiments described herein are not restrictive, but may be modified within the spirit and scope. The technical features described in different embodiments may be combined as appropriate within the scope of the invention.

1. A temperature stimulation unit installable on a back of a touch portion touchable by a player to provide a sense of a temperature different from an ordinary temperature to the player, the temperature stimulation unit comprising:
a cover configured to come in contact with the back of the touch portion;
a case comprising a top portion with an opening through which the cover is exposed; and
components accommodated in the case, the components comprising
a temperature changer located on a back surface of the cover and configured to change a temperature of the cover,
a heat sink located opposite to the cover across the temperature changer, and
a control board configured to control an operation of the temperature changer, wherein
the case comprises a bottom portion opposite to the top portion across the components and comprises a side portion connecting the top portion and the bottom portion, and the bottom portion and the side portion have a through-hole, and
the bottom portion and the side portion define a clearance at least with the control board.

2. The temperature stimulation unit according to claim 1, wherein
the bottom portion and the side portion define a clearance with the components.

3. The temperature stimulation unit according to claim 1, wherein
the control board is between the heat sink and the bottom portion, and
the case comprises a support on an inner surface of the bottom portion, and the support supports the control board with a clearance left between the control board and the bottom portion.

4. The temperature stimulation unit according to claim 1, wherein
the through-hole comprises a through-hole extending from the bottom portion to the side portion at a corner connecting the bottom portion and the side portion.

5. The temperature stimulation unit according to claim 1, wherein
the temperature changer comprises a Peltier element.

6. An amusement machine, comprising:
a touch portion touchable by a player to provide a sense of a temperature different from an ordinary temperature to the player; and
the temperature stimulation unit according to claim 1 on a back of the touch portion.

7. The temperature stimulation unit according to claim 2, wherein
the control board is between the heat sink and the bottom portion, and
the case comprises a support on an inner surface of the bottom portion, and the support supports the control board with a clearance left between the control board and the bottom portion.

8. The temperature stimulation unit according to claim 2, wherein
the through-hole comprises a through-hole extending from the bottom portion to the side portion at a corner connecting the bottom portion and the side portion.

9. The temperature stimulation unit according to claim 3, wherein
the through-hole comprises a through-hole extending from the bottom portion to the side portion at a corner connecting the bottom portion and the side portion.

10. The temperature stimulation unit according to claim 7, wherein
the through-hole comprises a through-hole extending from the bottom portion to the side portion at a corner connecting the bottom portion and the side portion.

11. The temperature stimulation unit according to claim 2, wherein
the temperature changer comprises a Peltier element.

12. The temperature stimulation unit according to claim 3, wherein
the temperature changer comprises a Peltier element.

13. The temperature stimulation unit according to claim 4, wherein
the temperature changer comprises a Peltier element.

14. The temperature stimulation unit according to claim 7, wherein
the temperature changer comprises a Peltier element.

15. The temperature stimulation unit according to claim 8, wherein
the temperature changer comprises a Peltier element.

16. The temperature stimulation unit according to claim 9, wherein
the temperature changer comprises a Peltier element.

17. An amusement machine, comprising:
a touch portion touchable by a player to provide a sense of a temperature different from an ordinary temperature to the player; and
the temperature stimulation unit according to claim 2 on a back of the touch portion.

18. An amusement machine, comprising:
a touch portion touchable by a player to provide a sense of a temperature different from an ordinary temperature to the player; and
the temperature stimulation unit according to claim 3 on a back of the touch portion.

19. An amusement machine, comprising:
a touch portion touchable by a player to provide a sense of a temperature different from an ordinary temperature to the player; and
the temperature stimulation unit according to claim 4 on a back of the touch portion.

20. An amusement machine, comprising:
a touch portion touchable by a player to provide a sense of a temperature different from an ordinary temperature to the player; and
the temperature stimulation unit according to claim 5 on a back of the touch portion.
